(19) United States
(12) Patent Application Publication
(10) Pub. No.: US 2008/0073751 A1
(43) Pub. Date: Mar. 27, 2008

(54) Memory cell and method of manufacturing thereof

(76) Inventor: Rainer Bruchhaus, Muenchen (DE)

Correspondence Address: SLATER & MATSIL LLP, 17950 PRESTON ROAD, SUITE 1000, DALLAS, TX, 75252, US

(21) Appl. No.: 11/525,196

(22) Filed: Sep. 21, 2006

(51) Int. Cl. H01L 29/12

(52) U.S. Cl. 257/613

(57) ABSTRACT

A memory cell includes a substrate, a first electrode disposed over the substrate a resistance element disposed over the first electrode, a second electrode disposed over the resistance element, the second electrode comprising an alloy, the alloy being formed from a first metal layer deposited on the resistance element, a second metal layer deposited on the first metal layer and heating the first and second metal layers.

### TECHNICAL FIELD

The present invention relates generally to semiconductors, and more particularly to a memory cell and method of manufacturing a memory cell.

### BACKGROUND

A semiconductor memory may include resistive elements for storing information. Such resistive memory cells may include a conductive bridging memory cells having a CB-contact (CBJ, CB-junction). For such a memory cell, a conductive channel (such as a conductive filament) may be formed through an isolation or matrix material. Writing or programming, as well as erasing, data in such memory cells may be accomplished by applying a desired, appropriate positive or negative voltage pulse. GeSe and GeS glass may be used as a matrix material. Silver and/or copper may be used as appropriate metals for forming the conductive channels. Tungsten may be used as an inert opposing electrode. Depositing silver or copper over the matrix material may result in a rough surface and/or surface with a granular morphology. An uneven surface may cause problems, for example so-called “micro-masking” during subsequent structuring steps, for example during subsequent etching such as reactive ion etching.

### SUMMARY OF THE INVENTION

In one embodiment of the invention, a memory cell includes a substrate, a first electrode arranged on the substrate, a resistance element arranged on the first electrode, a second electrode arranged on the resistance element, wherein the second electrode includes an alloy, wherein the alloy was formed from a first metal layer deposited on the resistance element, a second metal layer deposited on the first metal layer and heating the first and second metal layers.

### BRIEF DESCRIPTION OF THE DRAWINGS

Features and advantages of the invention may be readily appreciated by persons skilled in the art from the following detailed description of exemplary embodiments thereof, as illustrated in the accompanying drawings, in which:

FIG. 1 illustrates an exemplary embodiment of a memory element;

FIG. 2 illustrates an exemplary method of fabricating a memory element;

FIGS. 3A-3E illustrate exemplary steps in an exemplary embodiment of a method of fabricating a memory element; and

FIG. 4 illustrates an exemplary memory circuit.

### DETAILED DESCRIPTION OF ILLUSTRATIVE EMBODIMENTS

In the following detailed description and in the several figures of the drawing, like elements are identified with like reference numerals.

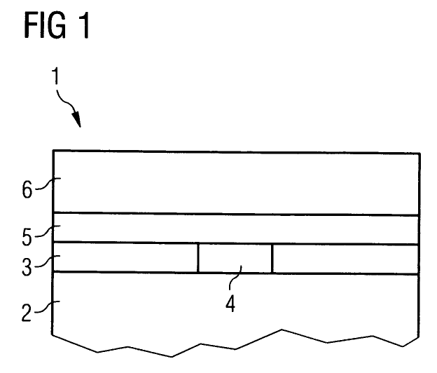

FIG. 1 illustrates an exemplary embodiment of a memory cell 1. In an exemplary embodiment, the memory cell 1 may include a substrate 2, an Si₃N₄ layer 3, a bottom electrode 4, a matrix layer 5 and a top electrode layer 6. In an exemplary embodiment, the substrate 2 may be a silicon substrate. In an exemplary embodiment, the substrate may be about 600 μm to about 800 μm thick. In an exemplary embodiment, the memory cell 1 may be a conductive bridging RAM (CBRAM) memory cell, for example, a solid state electrolyte cell including a solid state electrolyte, which may be made of chalcogenide material. In an exemplary embodiment, the memory cell 1 may be an integrated memory arrangement based on resistive memory cells.

In the context of this description chalcogenide material is to be understood, for example, as any compound containing sulfur, selenium, germanium and/or tellurium. In accordance with one embodiment of the invention, the ion conducting material is, for example, a compound, which is made of a chalcogenide and at least one metal of the group I or group II of the periodic system, for example arsene-trisulfide-silver. Alternatively, the chalcogenide material contains germanium-sulfide (GeS), germanium-selenide (GeSe), tungsten oxide (WOₓ), copper sulfide (CuS) or the like. The ion conducting material may be a solid state electrolyte.

Furthermore, the ion conducting material can be made of a chalcogenide material containing metal ions, wherein the metal ions can be made of a metal, which is selected from a group consisting of silver, copper and zinc or of a combination or an alloy of these metals.

In an exemplary embodiment, a Si₃N₄ layer 3 may be deposited over the substrate 2. The Si₃N₄ layer 3 descriptively provides an isolation between the contact plugs that will be formed in succeeding processes. In another embodiment of the invention, the layer 3 may be formed of SiO₂. In an exemplary embodiment, the Si₃N₄ layer may be deposited by chemical vapor deposition (CVD) according to the following chemical reaction: SiH₄+NH₃→Si₃N₄. In an exemplary embodiment, the Si₃N₄ layer may have a thickness within a range of about 100 nm to about 200 nm.

In an exemplary embodiment, the memory cell 1 may include a bottom electrode 4, for example, bottom inert cathode. In an exemplary embodiment, the bottom electrode 4 may include tungsten. In an exemplary embodiment, the bottom electrode 4 may be formed in the Si₃N₄ layer. In an exemplary embodiment, the bottom electrode 4 may be formed by depositing the Si₃N₄ layer, followed by a lithographical structuring of the Si₃N₄ layer using anisotropic etching, e.g., reactive ion etching (RIE). Next, tungsten (W) is deposited on the resulting structure followed by a chemical mechanical polishing process (CMP). In an exemplary embodiment, the bottom electrode may have a thickness in a range from about 100 nm to about 200 nm, for example.

In an exemplary embodiment, the memory cell 1 may include a matrix layer 5. In an exemplary embodiment, the matrix layer 5 may include a chalcogen or chalcogenide. In an exemplary embodiment, the matrix layer 5 may include GeS or GeSe, for example, GeS or GeSe glass. In an exemplary embodiment, the matrix layer 5 may have a thickness in a range from about 20 nm to about 80 nm, for example about 50 nm thick. In an exemplary embodiment, the matrix layer 5 may be deposited, for example using a sputter technique.

In an exemplary embodiment, the top electrode layer 6 may be, for example, a top active anode. In an exemplary embodiment, the top electrode layer 6 may include a germanium/copper (Ge/Cu) alloy. In an exemplary embodiment, the top electrode layer may have a thickness in a range from about 100 nm to about 210 nm, for example about 170 nm. In an exemplary embodiment, the top electrode layer may include Cu₃Ge and/or CuxGe. In an exemplary embodiment, the top electrode layer may be a ζ-phase or an ε₁-phase. In an exemplary embodiment, the phase may depend, at least in part, on the relative percentages of copper and germanium in the alloy.

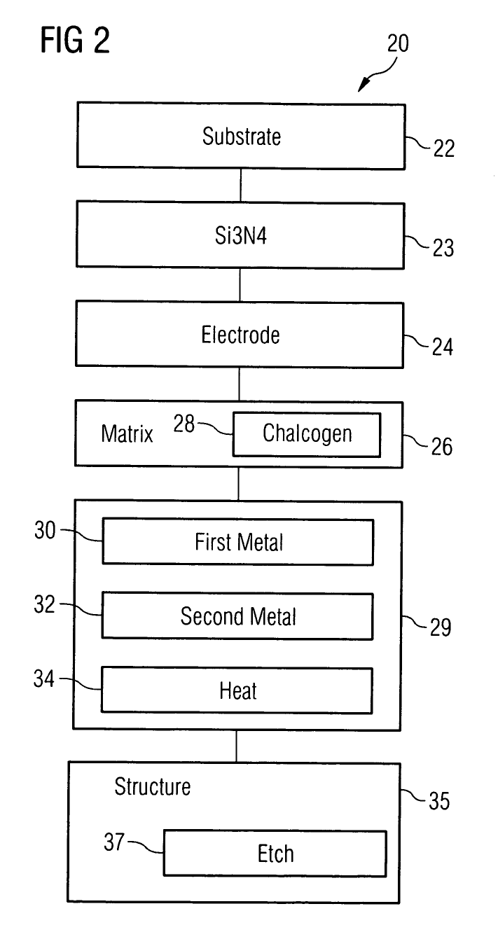

In an exemplary embodiment, a top electrode 6 including an ε₁-phase with about 25% Ge to about 35% Ge may have a specific resistance of about 10 uOhm/cm. In an exemplary embodiment, increasing the percentage of Ge further may increase the specific resistance of the top electrode 6. In an exemplary embodiment, a top electrode 6 including about 50% Ge may have a specific resistance of about 46 μOhm/cm. In this context it should be mentioned that it may be advantageous that the specific resistance is as low as possible. In one exemplary embodiment, the top electrode layer is an ε₁ phase. In an exemplary embodiment, the top electrode layer 6 may be formed in accordance with a method discussed below with respect to FIGS. 2 and/or 3A-H.

FIG. 2 illustrates an exemplary embodiment of a method 20 for forming a memory cell 1 (FIG. 1), for example, a memory cell with a bottom electrode, a matrix layer and a top electrode layer.

In an exemplary embodiment, the method 20 may include providing 22 a substrate 2 (FIG. 1). In an exemplary embodiment, the method 20 may include providing 23 a layer of Si₃N₄ 3 (FIG. 1) deposited on the substrate 2 (FIG. 1).

In an exemplary embodiment, the method 20 may include providing 24 a bottom electrode 4 (FIG. 1) on the substrate 2 (FIG. 1). In an exemplary embodiment, the bottom electrode 4 may be formed by depositing the Si₃N₄ layer, followed by a lithographical structuring of the Si₃N₄ layer using anisotropic etching, e.g., reactive ion etching (RIE). Next, tungsten (W) is deposited on the resulting structure followed by a chemical mechanical polishing process (CMP).

In an exemplary embodiment, the method 20 may include providing 26 a matrix layer 5 (FIG. 1). In an exemplary embodiment, providing 26 the matrix layer may include providing a chalcogen layer, for example, a layer of GeSe or GeS, on the substrate. In an exemplary embodiment, providing 26 the matrix layer may include depositing 28 a chalcogen using a sputter technique. In an exemplary embodiment, the matrix layer may have a thickness in a range from about 20 nm to about 80 nm.

In an exemplary embodiment, the method 20 may include providing 29 a top electrode layer 6 (FIG. 1). In an exemplary embodiment, providing 29 the top electrode layer 6 (FIG. 1) may include depositing 30 a first metal layer, depositing 32 a second metal layer and heating 34 the first and second metal layers.

In an exemplary embodiment, the method 20 may include depositing 30 a first metal. In an exemplary embodiment, the first metal layer may include a first metal, for example, germanium (Ge). In an exemplary embodiment, the first metal layer, for example germanium, may be deposited 30 over the matrix layer 5 (FIG. 1) or chalcogen layer. In an exemplary embodiment, the first metal layer may have a thickness in a range from about 25 nm to about 50 nm, for example about 35 nm. In an exemplary embodiment, the first metal layer may be deposited 30 using a sputter technique.

In an exemplary embodiment, the method 20 may include depositing 32 a second metal layer. In an exemplary embodiment, the second metal layer may be deposited 32 over the first metal layer. In an exemplary embodiment, the second metal layer may include a second metal, for example copper. In an exemplary embodiment, the first and second metals may be different metals. In an exemplary embodiment, the second metal layer may be deposited 32 using a sputter technique. In an exemplary embodiment, the second metal layer may have a thickness in a range from about 80 nm to about 160 nm, for example about 120 nm.

In an exemplary embodiment, the method 20 may include heating 34 at least the first and second metal layers. In an exemplary embodiment, the method 20 may include heating 34 the substrate with the matrix layer and the first and second metal layers. In an exemplary embodiment, the method 20 may include heating 34 the first and second metal layers to a temperature at which the first and second metal layers react with one another to form an alloy. In an exemplary embodiment, the reaction may occur at temperatures at least above about 125° C.

In an exemplary embodiment, heating 34 may include heating 34 to a temperature of at least above 125° C. and no more than about 400° C., for example, to a temperature of about 150° C. In an exemplary embodiment, heating above 400° C. to about 600° C. may destroy the chalcogenide material.

In an exemplary embodiment, heating 34 may include placing the substrate along with the matrix layer and the first and second metal layers in a furnace for about 30 minutes.

In an exemplary embodiment, the relative percentage of the first and second metals in the alloy may, at least in part, determine the particular phase of alloy to be formed during heating. In an exemplary embodiment, the relative thicknesses of the first and second metal layers may determine, at least in part, the particular phase of an alloy to be formed in a subsequent heating of the layers. In an exemplary embodiment for the formation of a high copper content alloy (for example with 5% Ge), the so-called ζ-phase may be formed. In an exemplary embodiment with a higher Ge percentage (for example about 25% Ge), the alloy formed may include the ε1 phase. In an exemplary embodiment, the ε1 phase may have the lowest specific resistance.

In an exemplary embodiment, the lowest specific resistance of the alloy may be about 10 μOhm/cm. In an exemplary embodiment, the alloy phase with the lowest specific resistance may be formed up to a Ge content of about 35%. In an exemplary embodiment, when the Ge content is higher than about 35%, the specific resistance of the alloy or phase may increase. In an exemplary embodiment, the specific resistance may increase to about 46 μOhm/cm with a Ge content of about 50%.

In an exemplary embodiment, the method 20 may include structuring 35. In an exemplary embodiment, structuring 35 may include, for example, etching 37, for example, reactive ion etching. In an exemplary embodiment, structuring 35 may include etching to define the structure of various features of the memory cell 1. In an exemplary embodiment, structuring 35 may include reactive ion etching to the Si₃N₄ layer.

In an exemplary embodiment, a top electrode layer 6 (FIG. 1) may have sufficiently low surface roughness to reduce “micro-masking” effects to an acceptable level. In an exemplary embodiment, the surface may have a relatively non-granular morphology.

In an exemplary embodiment, the top electrode layer 6 (FIG. 1) may be smoother than a surface formed of copper without germanium or silver. In an exemplary embodiment, the surface with a relatively smoother or less-granular morphology may provide for more accurate structuring during subsequent structuring steps, for example, reactive ion etching. In an exemplary embodiment, a top electrode may reduce “micro-masking” effects that may result from rough or rougher surfaces during subsequent etch steps.

In an exemplary embodiment, the method 20 may provide 29 a top electrode layer 6 (FIG. 1) which includes copper but for which copper was not deposited directly over the matrix material. Providing 29 the top electrode layer 6 without depositing the second metal, for example, copper or silver, directly on a matrix material, for example, a chalcogen such as GeS or GeSe, may provide a smoother surface than methods in which copper or silver, or alloys containing copper or silver, are deposited directly on the matrix material.

In an exemplary embodiment, copper and/or silver molecules deposited directly on a matrix material may transport through the surface of the matrix material and form a raw, granular morphology. A granular morphology may be undesirable during following structure steps with reactive etching due, at least in part, to undesirable “micro-masking” effects.

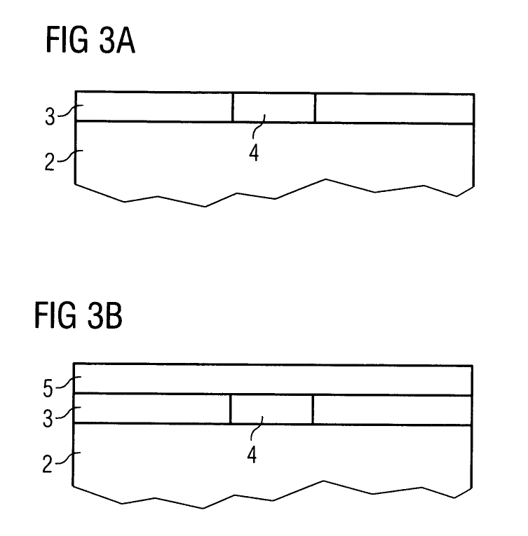

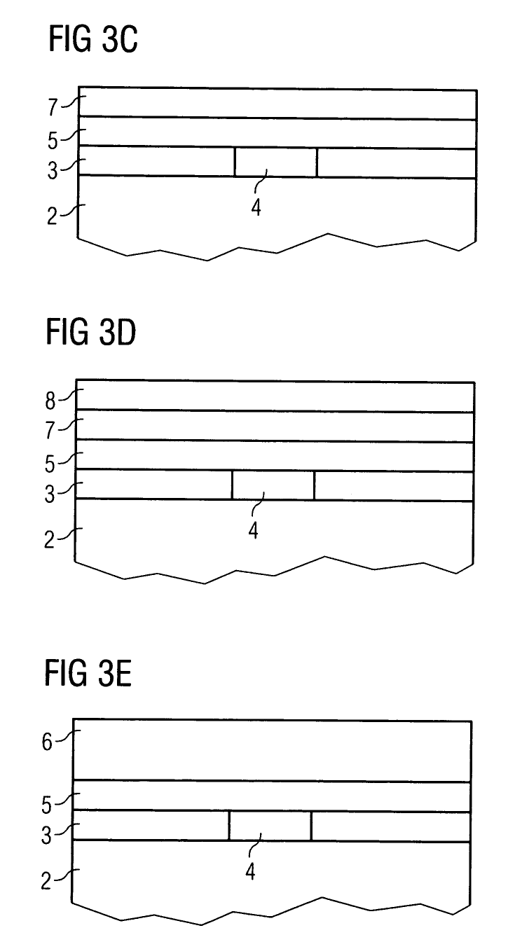

FIGS. 3A through 3F illustrate exemplary steps in an exemplary method for forming a top electrode, matrix layer and a bottom electrode. FIG. 3A illustrates an exemplary embodiment of a substrate having an Si₃N₄ layer 3 and a bottom electrode portion 4. In an exemplary embodiment, the bottom electrode portion may include tungsten.

FIG. 3B illustrates an exemplary embodiment of a matrix layer 5 over a substrate. In an exemplary embodiment, the matrix layer 5 may include a chalcogen. In an exemplary embodiment, the matrix layer may include a layer of GeS and/or GeSe.

FIG. 3C illustrates an exemplary embodiment of a substrate 2, an SiN₄ layer with a bottom electrode 4, a matrix layer 5 and a first metal layer 7 over the matrix layer 5. In an exemplary embodiment, the first metal layer 7 may include germanium. FIG. 3D illustrates an exemplary embodiment of the embodiment of FIG. 3C with a second metal layer 8 over the first metal layer 7. In an exemplary embodiment, the second metal layer 8 may include copper.

FIG. 3E illustrates an exemplary embodiment of the embodiment of FIG. 3D after heating. In an exemplary embodiment, assembly may include a top electrode 6, which may include an alloy. In an exemplary embodiment, the alloy 6 may include a metal included in a first metal layer 7 and a metal included in a second metal layer 8. In an exemplary embodiment, the top electrode layer 6 may include an alloy formed by heating first and second metal layers 7, 8. In an exemplary embodiment, the assembly may have been heated in the temperature range of 150° C. to 400° C. for about one hour in a closed tube furnace under purified He gas.

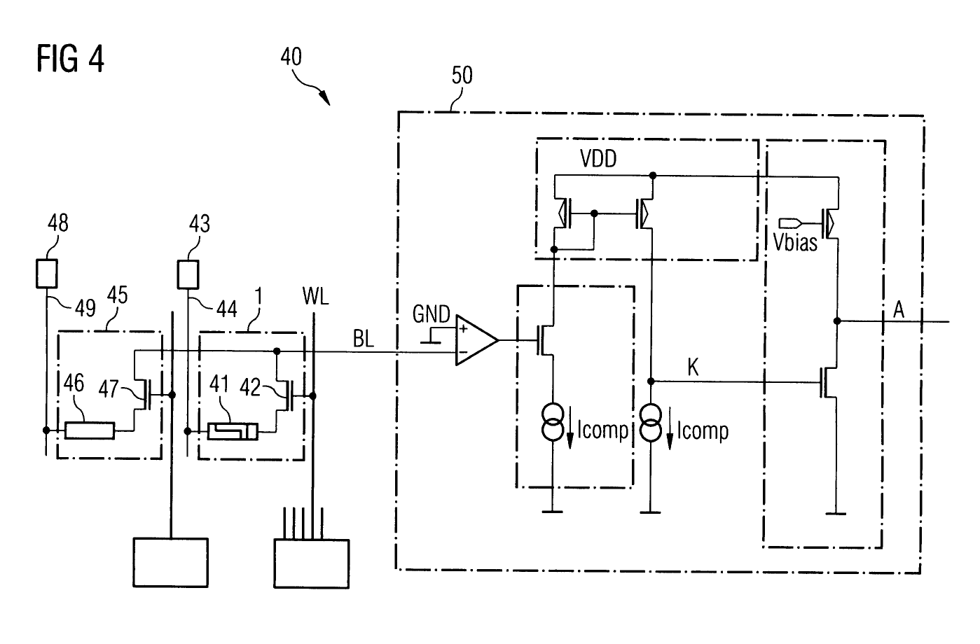

FIG. 4 illustrates a detail of an exemplary embodiment of a memory circuit 40. In an exemplary embodiment, the memory circuit 40 may include a memory cell 1. In an exemplary embodiment, the memory cell 1 may be a CBRAM memory cell. In an exemplary embodiment, the memory cell 1 may be connected to a word line WL and a bit line BL. In an exemplary embodiment, the wordline WL and bit line BL may run essentially perpendicular to one another and at the crossover point of which the memory cell 1 is arranged. In an exemplary embodiment, the memory cell 1 may include, by way of example, a multiplicity of cells in a matrix formed from word lines WL and bit lines BL.

In an exemplary embodiment, the memory cell 1 may include a resistance element 41 and a selection switch 42, for example a selection transistor. In an exemplary embodiment, the resistance element 41 may include at least a portion of a matrix layer 5 (FIG. 1) and may be a CBRAM resistance element. In an exemplary embodiment, the resistance element 41 may be connected to a read voltage source 43 by a first terminal and via a read voltage line 44. In an exemplary embodiment, a second terminal of the resistance element 41 may be connected to a first terminal of the selection switch 42, and a second terminal of the selection switch 42 may be connected to the bit line BL. In an exemplary embodiment, a control terminal of a selection switch 42 may be connected to the word line WL, so that the selection switch 42 may be opened or closed by an activation signal on the word line WL.

In an exemplary embodiment, the resistance element 41 may be essentially constructed with a matrix layer 5 situated between two electrodes 4, 6 (FIG. 1). Through suitable application of a programming current, it may be possible to form or withdraw conductive paths in the solid electrolyte and thus to set the resistance of the resistance element 41 by means of previous programming with a programming current. In this way, it may be possible to set the resistance of the resistance element 41 in different resistance ranges corresponding to different states of the resistance element 41, and thereby to store an item of information as a memory datum.

In an exemplary embodiment, the memory circuit 40 may include a reference resistance cell 45, a reference resistance element 46 and a reference selection switch 47. In an exemplary embodiment, the reference resistance cell 45 may be arranged on the same bit line as the memory cell 1. In an exemplary embodiment, for example a memory having an array or matrix having a plurality of bit lines and a plurality of word lines, a reference resistance cell 45 may be provided on each of the bit lines. In an exemplary embodiment, the reference selection switch 47 may be connected by a first terminal to the bit line BL and by a second terminal to a first terminal of the reference resistance element 46. In an exemplary embodiment, a second terminal of the reference resistance element 46 may be connected to a reference voltage source 48 via a reference voltage line 49. A control terminal of the reference selection switch 47 may be connected to a reference line 49, so that the reference selection switch 47 may be turned on or turned off in a manner dependent on a signal on the reference line 49.

In an exemplary embodiment, memory circuit 40 may include an evaluation unit 50 that, in the event of the read-out of the relevant memory cell 1, may evaluate a current flowing from or onto the bit line BL and assigns it to a memory datum. The corresponding memory datum is output with the aid of a logic level at an output A of the evaluation unit 50.

While the foregoing is directed to exemplary embodiments of the present disclosure, other and further embodiments of the disclosure may be devised without departing from the basic scope thereof.

What is claimed is:

1. A memory cell, comprising:
a substrate;
a first electrode disposed over the substrate;
a resistance element disposed over the first electrode; and
a second electrode disposed over the resistance element;
wherein the second electrode comprises an alloy of first metal and a second metal.

2. The memory cell according to claim 1, wherein the second electrode is formed by depositing the first metal on the resistance element, depositing the second metal on the first metal and heating the first and second metals.

3. The memory cell according to claim 1, wherein the resistance element comprises a solid electrolyte material.

4. The memory cell according to claim 1, wherein the resistance element comprises a chalcogen or chalcogenide.

5. The memory cell according to claim 4, wherein the resistance element comprises GeS and/or GeSe.

6. The memory cell according to claim 1, wherein the first metal comprises germanium.

7. The memory cell according to claim 1, wherein the second metal comprises copper.

8. The memory cell according to claim 1, wherein the first metal comprises germanium and the second metal comprises copper.

9. A memory cell comprising:
a substrate;
a first electrode disposed over the substrate;
a matrix layer disposed over the first electrode, the matrix layer comprising solid electrolyte material; and
a second electrode arranged on the matrix layer, the second electrode comprising an alloy comprising a first metal and a second metal, the second electrode being formed by depositing a first metal layer comprising the first metal, depositing a second metal layer comprising the second metal, and heating the first and second metals to form the alloy, the first metal layer comprising germanium and the second metal comprising at least one of copper and/or silver.

10. A method of manufacturing a memory cell, the method comprising:
forming a first electrode layer on or above a substrate;
forming a matrix layer on or above the first electrode layer;
forming a first metal layer on or above the matrix layer, the first metal layer comprising a first metal;
forming a second metal layer on or above the first metal layer, the second metal layer comprising a second metal; and
heating the first and second metal layers, wherein heating comprises heating the first and second metal layers to a temperature at which an alloy comprising the first metal and the second metal forms.

11. The method in accordance with claim 10, wherein the first electrode layer comprises tungsten.

12. The method in accordance with claim 10, wherein the matrix layer comprises a solid state electrolyte material.

13. The method in accordance with claim 10, wherein the matrix layer comprising at least one of GeS and/or GeSe.

14. The method in accordance with claim 10, the first metal comprises germanium.

15. The method in accordance with claim 10, the second metal comprises copper or silver.

16. The method in accordance with claim 10, the first metal comprises germanium and the second metal comprises copper or silver.

17. A method of manufacturing a memory cell, comprising:
forming a tungsten electrode on or above a silicon substrate;
forming a matrix layer on or above the tungsten electrode, the matrix layer comprising a solid electrolyte material;
forming a germanium layer over the matrix layer;
forming a copper layer over the germanium layer; and
heating the copper layer and the germanium layer to form an alloy comprising germanium and copper.
